(19) United States
(12) Patent Application Publication
(10) Pub. No.: US 2003/0117231 A1
(43) Pub. Date: Jun. 26, 2003

(54) Switched power combiner with adjustable impedance-matching transformer

(75) Inventor: Kevin C. Gerlock, Santa Clarita, CA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: SPECTRIAN CORPORATION, Sunnyvale, CA

(21) Appl. No.: 10/026,863

(22) Filed: Dec. 21, 2001

(51) Int. Cl. H03H 7/48

(52) U.S. Cl. 333/124; 333/101

(57) ABSTRACT

To avoid VSWR degradation associated with using a fixed impedance matching transformer in an RF power amplifier combiner, the transformer is configured as an adjustable-impedance matching transformer, that maintains a relatively low voltage standing wave ratio at the combiner's output port, as the number of amplifiers is changed. The adjustable impedance transformer may comprise a section of transmission line conductor and an adjacent dielectric medium, the dielectric constant of which is controllably variable. The dielectric medium may comprise a shaped dielectric element, that is positionable relative to the transmission line conductor, so as to provide a variable dielectric constant and thereby allow the effective impedance of the transformer to be varied among respectively different values based upon the number of amplifiers being combined.

### FIELD OF THE INVENTION

The present invention relates in general to communication systems and components therefor, and is particularly directed to a new and improved switched RF power amplifier combiner, that employs an adjustable impedance-matching transformer used to couple a summing node for multiple power amplifiers to an output port of the power combiner in a manner that maintains a relatively low voltage standing wave ratio.

### BACKGROUND OF THE INVENTION

In order to attain the power levels required for everyday commercial applications, such as in a base station of a wireless RF communication system, it is common practice to implement a transmitter's main RF power amplifier as a plurality of parallel-connected RF amplifier modules, whose outputs are combined to produce a composite amplified signal. In addition, it is often the case that an application may initially employ only a single amplifier and then add further amplifier modules as power requirements increase.

In a typical RF power amplifier combiner architecture, diagrammatically illustrated in FIG. 1, a plurality of amplifier modules 10-1, 10-2, . . . , 10-N are coupled in parallel with their outputs coupled through respective sections of transmission line 12-1, 12-2, . . . . ,12-N (having a characteristic impedance Z₀) to a common summing node 14. As a result of the parallel circuit architecture, the effective impedance Z_{c} at the common node is equal to the amplifier system impedance Z₀ (e.g., Z₀) divided by the number N of amplifier modules 10, so that Z_{c}=Z₀/N.

In order to achieve an acceptably low tolerance (exactly at or in the neighborhood of a value of 1.0) of voltage standing wave ratio (VSWR) at an output port 16 from which the combined RF amplifier energy is produced, it is common practice to insert an impedance-matching transformer 18 between the common node 14 and the output port 16 (which is usually coupled to the transformer via an output transmission line section 19 of characteristic impedance Z₀). The impedance-matching transformer 18 has an electrical length of a quarter-wavelength of the RF carrier frequency of interest, and is designed so that its transfer function ideally transforms the divided impedance Z_{c} to a transformed impedance Z_{T} that exactly matches the impedance of the output port (which usually corresponds to the characteristic impedance Z₀ of the amplifier system).

Because such an impedance-matching transformer is designed for a fixed number of amplifiers, its functionality is significantly reduced, if the number of amplifiers is changed (added or removed), causing the VSWR at the output port to degrade, resulting in reflected power loss. For example, where the impedance-matching amplifier is designed for a four (N=4) RF power amplifier system, the VSWR will increase as follows for reduction in the number of amplifiers: 1.33:1 for three amplifiers; 2.0:1 for two amplifiers; and 4.0:1 for one amplifier.

### SUMMARY OF THE INVENTION

Pursuant to the invention, this VSWR degradation problem is substantially abated, by configuring the impedance-matching transformer as an adjustable-impedance transformer, that is effective to maintain a relatively low voltage standing wave ratio at the combiner's output port, as the number of amplifiers is changed. The adjustable impedance transformer comprises a section of transmission line conductor and an adjacent dielectric medium, the dielectric constant of which is controllably variable. The dielectric medium may comprise a shaped dielectric element, that is positionable relative to the transmission line conductor, so as to provide a variable dielectric constant and thereby allow the effective impedance of the transformer to be varied among respectively different values based upon the number of amplifiers being combined.

The shaped dielectric element may be formed by a plurality of regions of respectively different thickness and lengths, so as to realize a stepped configuration, that is controllably translatable along the surface of a ground plane, so as to place a selected one of the steps or regions of the dielectric element in juxtaposition with the transmission line conductor, based upon the number of amplifiers being combined. The steps of the dielectric element have respectively different lengths, to ensure that the effective electrical length of the transformer is exactly one-quarter wavelength for the impedance of interest. Translation of the dielectric element may be accomplished by manual positioning preferably with an index to establish proper location, or a driven actuator, such as solenoid actuator, stepping motor and the like, whose output is coupled through a drive coupling to position the dielectric medium.

In a combiner architecture that is capable of combining the outputs of up to four RF power amplifiers, the matching transformer ostensibly requires four different values of (variable) transformer impedance Z_{VAR}. However, its relatively proximate impedance values (28.87 and 25 ohms) for the three and four amplifier designs allows a reasonably low value of VSWR (Z_{T}/Z_{c}=1.15:1−23 dB return loss) to be achieved for the same value of transformer impedance Z_{VAR}, that is the geometric mean ((Z_{VAR}*Z_{VAR4})^{1/2}=(28.87*25)^{1/2}=26.86 ohms) between the two values. Using the same impedance for both a three and a four RF power amplifier means that the transformer need only provide three different values of impedance, rather than four. This three impedance variability to accommodate any of a one, two, three or four amplifier combiner can be achieved by using a two-step dielectric element to change the impedance of the transformer.

For the case of a single amplifier, the stepped dielectric element is positioned so as to be sufficiently spaced apart from the transmission line conductor, such that the effective dielectric constant of the transformer is that (1.0) of the air between the conductor and the ground plane. For a two amplifier combiner, the stepped dielectric element is positioned SO as to place the first, relatively thinner of its two steps directly beneath the transmission line conductor, thereby producing an effective dielectric constant (2.0) defined by air and material of the thinner step beneath the conductor. To combine the outputs of either three or four power amplifiers, the stepped dielectric element is positioned so as to place the relatively thicker of the two steps directly beneath transmission line conductor, so that the effective dielectric constant (3.465) is defined by the combination of air and material of the step directly beneath the conductor.

### BRIEF DESCRIPTION OF THE DRAWINGS

FIG. 1 diagrammatically illustrates a conventional RF power amplifier combiner architecture;

FIG. 2 diagrammatically illustrates a switched RF power amplifier combiner architecture employing a variable impedance-matching transformer in accordance with the invention;

FIG. 3 is a diagrammatic end view of a stepped configuration variable impedance-matching transformer; and

FIG. 4 is a diagrammatic top view of the stepped configuration variable impedance-matching transformer of FIG. 2.

### DETAILED DESCRIPTION

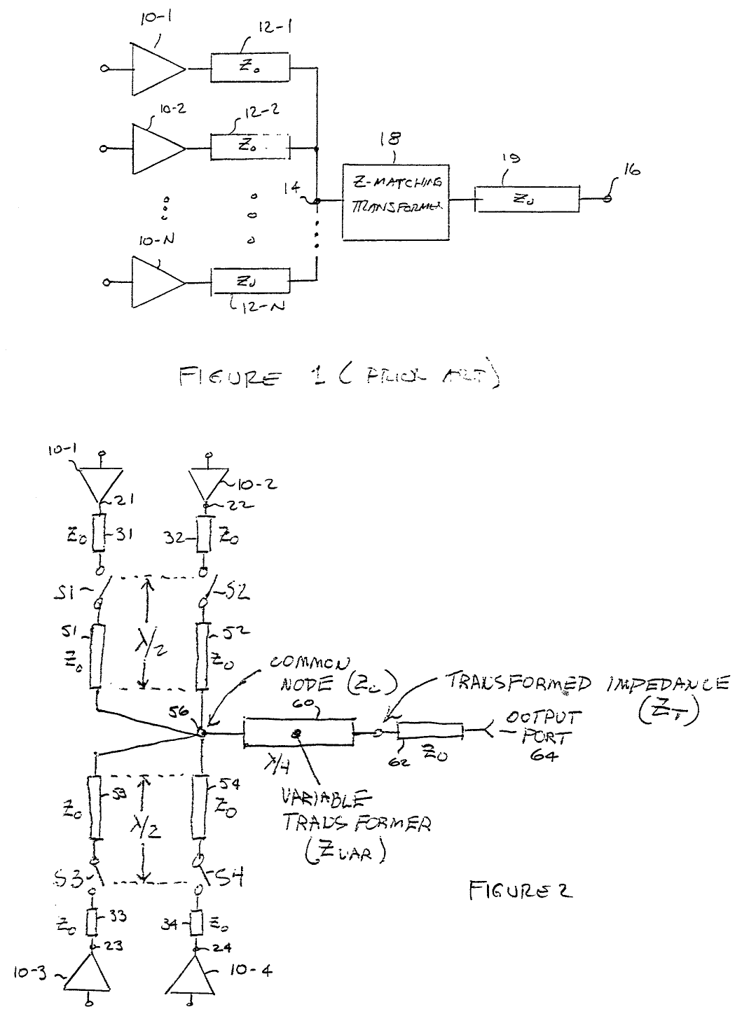

Attention is now directed to FIG. 2, which diagrammatically illustrates the architecture of a switched RF power amplifier combiner that employs the variable impedance-matching transformer of the invention. For purposes of providing a non-limiting example, the architecture of FIG. 2 shows a design that is capable of combining the outputs of up to four RF power amplifier modules. It should be observed, however, that the invention is not limited to this or any particular number N of RF power amplifier modules. A four module configuration has been shown merely for purposes of reducing the complexity of the illustration, and associated impedance and VSWR parameter calculations set forth below.

For a four RF power amplifier combiner, the architecture of FIG. 2 has a set of four combiner input ports 21, 22, 23 and 24, which are adapted to be coupled to respective outputs of four RF power amplifier modules 10-1, 10-2, 10-3 and 10-4. The combiner input ports are coupled through respective sections of transmission lines 31, 32, 33 and 34, each having a characteristic impedance Z₀, to switches S1, S2, S3, S4, outputs of which are coupled through respective transmission lines 51, 52, 53 and 54 (of characteristic impedance Z₀) to a summing or common node 56. When closed, a respective switch is operative to couple the output of its associated RF power amplifier to the common node 56. The effective electrical distance between the sections of transmission line 31, 32, 33 and 34 and the common node 56 is one-half wavelength of the RF carrier frequency of interest.

Similar to the RF power amplifier combiner architecture of FIG. 1, an impedance-matching transformer 60 (having an electrical length of a quarter-wavelength of the RF carrier frequency of interest) is coupled between the common node 56 and section of transmission line 62 (of characteristic impedance Z₀), which is coupled to an output port 64. However, unlike the transformer of FIG. 1, whose impedance is fixed and whose transfer function achieves a low (e.g., on the order of 1.0) VSWR for only a prescribed number of amplifiers, the impedance-matching transformer 60 of FIG. 2 has an impedance Z_{VAR}=(Z₀*Z_{c})^{1/2}, which is controllably variable based upon the number of RF power amplifiers whose outputs are to be combined.

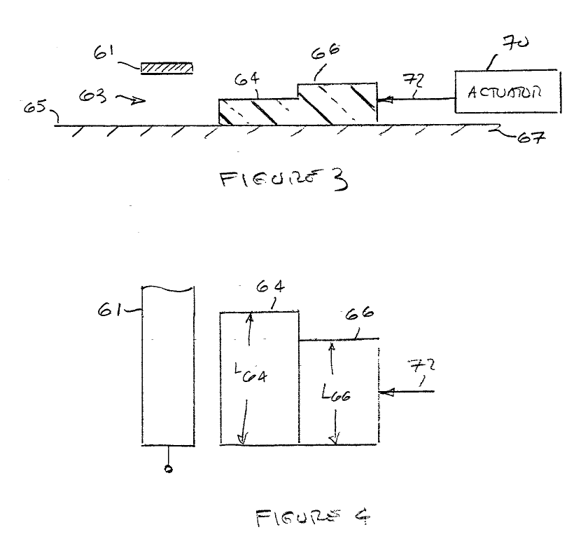

In accordance with a non-limiting implementation, shown diagrammatically in FIGS. 3 and 4, the impedance-matching transformer 60 may be configured as a length of transmission line conductor 61, and an adjacent length of dielectric medium 63, the dielectric constant of which is controllably variable. While the transmission line conductor 61 of the embodiment of FIGS. 3 and 4 is shown as having a generally rectangular cross-section, it is to be understood that the invention is not limited thereto, but may have a variety of other configurations. Non-limiting examples include a suspended substrate transmission line, slab lines (a round wire between a pair of ground planes), air dielectric microstrip and stripline, and a rectangular coaxial line.

For the illustrated embodiment, wherein the transmission line conductor 61 has a generally rectangular cross-section, the dielectric medium 63 may be configured as a section or slab of ‘shaped’ dielectric material, such as a ‘stepped’ section (for example having a pair of stepped portions 64 and 66 in the illustrated example) of nylon, phenolic, or polyurethane, as shown. In order to vary the impedance of the transformer, the shaped dielectric slab 63 may be placed adjacent to the conductor 61, for example as by being slidably translatable on the surface 65 of a ground plane 67, from a position spaced apart from being directly underneath the conductor (where the dielectric constant is that of air), so that the respectively different thickness portions or ‘steps’ 64 and 66 of the dielectric slab 63 may be controllably translated in juxtaposition with the conductor 61, and thereby vary the effective dielectric constant between the transmission line conductor 61 and the ground plane 67.

As shown in the plan view of FIG. 4, the steps 64 and 66 of the dielectric slab have respectively different lengths L₆₄ and L₆₆, to ensure that the effective electrical length of the transformer is exactly one-quarter wavelength for the impedance of interest. Controllable translation of the dielectric slab 63 relative to the transmission line conductor 61 may be accomplished in a number of ways including, but not limited to, manual positioning preferably with an index to establish proper location, or a driven actuator, shown at 70, such as solenoid actuator, stepping motor and the like, whose output is coupled through a drive coupling 72, so as to position the dielectric medium 63 to a selected one of a plurality of positions, based upon the number of RF power amplifiers whose outputs are to be combined.

In the up to four amplifier design of the present example, using a characteristic impedance of Z₀=50 ohms, the common node impedance Z_{c}, and associated transformer impedance Z_{VAR}, may be calculated for each of one through four amplifiers, as follows. For the case of only a single (N=1) amplifier, each of the common node impedance Z_{c}, the transformer impedance Z_{VAR} and the transformed impedance Z_{T}=(Z²_{VAR}) is the same (Z_{c}=Z_{VAR}=Z_{T}=Z₀=50 ohms). For N=2 amplifiers, the common node impedance Z_{c}=Z₀/2 =25 ohms, the transformer impedance Z_{VAR}=(50*25)^{1/2}=35.35 ohms; and the transformed impedance Z_{T}=(35.35)²/25=50 ohms; for N=3 amplifiers, the common node impedance Z_{c}=Z₀/3 =16.67 ohms, the transformer impedance Z_{VAR}=(50*16.67)^{1/2}=28.87ohms, and the transformed impedance Z_{T}=(28.87)²/16.67=50 ohms; and for N=4 amplifiers, the common node impedance Z_{c}=Z₀/4=12.50 ohms, the transformer impedance Z_{VAR}=(50*12.50)^{1/2=25} ohms, and the transformed impedance Z_{T}=(25)²/12.50=50 ohms.

Although a four amplifier configuration requires four different values of transformer impedance Z_{VAR}, its relatively proximate values (28.87 and 25 ohms) for the three and four amplifier designs allows a reasonably low value of VSWR (Z_{T}/Z_{c}=1.15:1−23 dB return loss) to be achieved for the same value of transformer impedance Z_{VAR}, that is the geometric mean ((Z_{VAR3}*Z_{VAR4})^{1/2}=(28.87*25)^{1/2}=26.86 ohms) between the two values. Using the same impedance for both a three and a four RF power amplifier means that the transformer need only provide three different values of impedance, rather than four.

This three impedance variability to accommodate any of a one, two, three or four amplifier combiner is readily achieved by the two-step dielectric element implementation of FIGS. 3 and 4. For the case of N=1, the slab 63 is positioned so as to be sufficiently spaced apart from the transmission line 61, such that the effective dielectric constant of the transformer is that (1.0) of the air between the conductor 61 and the ground plane 67. For N=2, the slab 63 is positioned so as to place the first, relatively thinner (step 64) of the two steps 64 and 66 directly beneath the transmission line 61, thereby producing an effective dielectric constant of 2.0 that is defined by air and material of the step 64 proper beneath the conductor 61. For each of N=3 and N=4, the slab 63 is positioned so as to place the second, relatively thicker (step 64) of the two steps 64 and 66 directly beneath transmission line 61, such that an effective dielectric constant of 3.465 is defined by the combination of air and material of the step 66 directly beneath the conductor 61.

As will be appreciated from the foregoing description, the above-described VSWR degradation problem associated with using a fixed impedance matching transformer in an RF power amplifier combiner can be substantially reduced by using an adjustable-impedance transformer, that is effective to maintain a relatively low voltage standing wave ratio at the combiner's output port, as the number of amplifiers is changed. For combining the outputs of up to four RF power amplifiers, the relatively proximate impedance values for a three amplifier combiner and a four amplifier combiner allows a reasonably low value of VSWR to be achieved for the same value of transformer impedance, that is the geometric mean of the two values for a three amplifier combiner and a four amplifier combiner. The ability to use the same impedance for both a three and a four RF power amplifier means that the transformer need only provide three different values of impedance, rather than four.

While I have shown and described an embodiment in accordance with the present invention, it is to be understood that the same is not limited thereto but is susceptible to numerous changes and modifications as known to a person skilled in the art, and I therefore do not wish to be limited to the details shown and described herein, but intend to cover all such changes and modifications as are obvious to one of ordinary skill in the art.

What is claimed:

1. An arrangement for combining outputs of a plurality of amplifiers comprising:
an input port adapted to be coupled to outputs of said plurality of amplifiers;
an output port to which combined outputs of said plurality of amplifiers are coupled; and
an impedance-matching transformer coupled between said input port and said output port and having an impedance that is adjustable among respectively different values in accordance with the number of amplifiers of said plurality.

2. The arrangement according to claim 1, wherein said amplifiers comprise RF power amplifiers.

3. The arrangement according to claim 1, wherein said impedance-matching transformer includes a section of transmission line conductor and a dielectric medium adjacent thereto, said dielectric medium being adapted to provide a variable dielectric constant and thereby vary the effective impedance of said transformer among said respectively different values in accordance with the number of amplifiers of said plurality.

4. The arrangement according to claim 3, wherein said dielectric medium has a stepped configuration.

5. The arrangement according to claim 4, wherein said dielectric medium comprises a plurality of regions of respectively different thickness and length and being controllably positionable so as to place a selected one of said plurality of regions in juxtaposition with said transmission line conductor in accordance with the number of amplifiers of said plurality.

6. The arrangement according to claim 1, further including:
a plurality of input terminals adapted to be coupled to outputs of respective ones of said plurality of amplifiers; and
a plurality of switches respectively coupled between said input terminals and said input port, and being operative to controllably couple outputs of said amplifiers to said input port.

7. The arrangement according to claim 1, wherein, for respectively different numbers of RF power amplifiers, said impedance-matching transformer is configured to provide a geometric mean of different impedances that match the impedance at said common node to an impedance at a transmission line coupled to said output port.

8. A method for combining outputs of a plurality of amplifiers comprising the steps of:
(a) combining outputs of said plurality of amplifiers at a common node; and
(b) coupling the combined outputs of said plurality of amplifiers at said common node through an impedance-matching transformer to an output port, said impedance-matching transformer having an impedance that is adjustable among respectively different values in accordance with the number of amplifiers of said plurality.

9. The method according to claim 8, wherein said amplifiers comprise RF power amplifiers.

10. The method according to claim 8, wherein said impedance-matching transformer comprises a section of transmission line conductor and a dielectric medium adjacent thereto, said dielectric medium being adapted to provide a variable dielectric constant and thereby vary the effective impedance of said transformer among said respectively different values in accordance with the number of amplifiers of said plurality.

11. The method according to claim 10, wherein said dielectric medium has a stepped configuration.

12. The method according to claim 11, wherein said dielectric medium comprises a plurality of regions of respectively different thickness and length, and wherein step (b) comprises controllably positioning said dielectric medium so as to place a selected one of said plurality of regions thereof in juxtaposition with said transmission line conductor in accordance with the number of amplifiers of said plurality.

13. The method according to claim 8, wherein step (a) comprises coupling a plurality of input terminals through respective switches to outputs of respective ones of said plurality of amplifiers, and closing selected ones of a plurality of switches respectively coupled between said input terminals and said common node, so as to controllably couple outputs of selected ones of said amplifiers to said common node.

14. The method according to claim 8, wherein, for respectively different numbers of amplifiers, said impedance-matching transformer is configured to provide a geometric mean of different impedances that match the impedance at said common node to an impedance at a transmission line coupled to said output port.

15. A method of coupling outputs of different numbers of RF power amplifiers to an output port while maintaining a prescribed voltage standing wave ratio tolerance at said output port, said method comprising the steps of:
(a) coupling a selected number of RF power amplifier outputs to a common node;
(b) coupling said common node to said output port through an impedance-matching transformer, which has an impedance that is adjustable among respectively different values, in accordance with the number of RF power amplifiers whose outputs are coupled to said common node in step (a); and
(c) adjusting the impedance of said impedance-matching transformer to a selected one of said respectively different values in accordance with said selected number of RF power amplifiers.

16. The method according to claim 15, wherein said impedance-matching transformer comprises a section of transmission line conductor and a dielectric medium adjacent thereto, said dielectric medium being adapted to provide a variable dielectric constant and thereby vary the effective impedance of said transformer among said respectively different values in accordance with said selected number of RF power amplifiers.

17. The method according to claim 16, wherein said dielectric medium has a stepped configuration.

18. The method according to claim 17, wherein said dielectric medium comprises a plurality of regions of respectively different thickness and length, and wherein step (b) comprises controllably positioning said dielectric medium so as to place a selected one of said plurality of regions thereof in juxtaposition with said transmission line conductor in accordance with said selected number of RF power amplifiers.

19. The method according to claim 15, wherein step (a) comprises coupling said RF power amplifier outputs through respective switches to said common node, and closing a selected number of said switches, so as to controllably couple outputs of selected ones of said plurality of RF power amplifiers to said common node.

20. The method according to claim 15, wherein, for respectively different numbers of RF power amplifiers, said impedance-matching transformer is configured to provide a geometric mean of different impedances that match the impedance at said common node to an impedance at a transmission line coupled to said output port.
